(19) United States
(12) Patent Application Publication
(10) Pub. No.: US 2015/0084640 A1
(43) Pub. Date: Mar. 26, 2015

(54) ANTENNA DIAGNOSTIS METHOD AND DEVICE

(71) Applicants: CONTINENTAL AUTOMOTIVE FRANCE, Toulouse (FR); CONTINENTAL AUTOMOTIVE GMBH, Hannover (DE)

(72) Inventors: Jean-Marie Quintin, Tournefeuille (FR); Rupert Schuster, Rohrbach (DE)

(73) Assignees: CONTINENTAL AUTOMOTIVE GMBH, Hannover (DE); CONTINENTAL AUTOMOTIVE FRANCE, Toulouse (FR)

(21) Appl. No.: 14/378,730

(22) PCT Filed: Feb. 14, 2013
(86) PCT No.: PCT/EP2013/000439

§ 371 Date: Aug. 14, 2014

(30) Foreign Application Priority Data
Feb. 17, 2012 (FR) 1200471

(51) Int. Cl. G01R 31/02; G01R 31/00

(52) U.S. Cl. CPC G01R 31/025; G01R 31/006
USPC 324/509; 324/538

(57) ABSTRACT

An antenna (L) diagnostic device of a resonant circuit associated with an amplifier includes a first transistor (HS1) and a second transistor (LS1) connected and an amplifier output (OUT1). The first transistor (HS1) and the second transistor (LS1) are mounted symmetrically and the amplifier output (OUT1) is located between the two transistors. The device includes: elements for measuring a current flowing in a connection of each of the transistors; first elements for generating an input signal connected to the first transistor; second elements for generating an input signal connected to the second transistor; and electronic elements (8) with an output supplying an output signal representative of the potential (V_OUT1) at the amplifier output. A method for diagnosing an antenna implementing such a device is also described.

The present invention relates to an antenna diagnostic method and device.

The present invention may find its application for example, but not exclusively, in a ‘hands free’ access system for a motor vehicle. Such a system can be used to access a motor vehicle, and possibly start it, without having to use a mechanical key. The user of the vehicle is then simply provided with an electronic card (also subsequently called a badge) which is detected and recognized by a control and management device associated with antennas arranged on board the vehicle. If the badge is identified by the control and management device as being an authorized badge for the vehicle, the user carrying this badge can enter the interior of the vehicle by simply grasping a door handle.

In the case of access on board a vehicle, the control and management device comprises a low frequency integrated circuit. This device is placed in the vehicle and transmits a signal using a carrier with a frequency of 125 kHz for example. When the card receives such a signal, it sends in turn a confirmation message (e.g. a 433 MHz UHF signal) with an identifier. If this identifier is recognized, the control and management device authorizes the unlocking of the vehicle doors.

Multiple antennas correspond to each control and management device. An RLC (Resistor, Inductor, Capacitor) circuit, or resonant circuit, corresponds to each antenna. The antenna itself is formed by the inductor of the corresponding circuit. In practice, the resistors and the capacitors of the various resonant circuits are arranged inside a housing in the vehicle and the corresponding inductors are arranged at a distance from the housing, e.g. in a door, the trunk, etc.

As in most electronic systems, the control and management device corresponding to the antennas of the ‘hands free’ system offers means, most often incorporating an analog-to-digital converter, for detecting operating faults in the antennas. In particular it is possible to determine whether the whole resonant circuit associated with an antenna is short-circuited with the power supply voltage or if it is short-circuited with the ground.

As described above, the inductor (or coil) of a resonant circuit is physically remote from the rest of the resonant circuit. It may then be useful to detect a fault which would appear in the antenna itself, i.e. in the inductor.

The object of the present invention is thus to provide an antenna diagnostic method and device which can also be used to detect faults in the antenna itself. The present invention will in particular enable detecting whether the inductor forming the antenna is short-circuited and/or if this inductor is in open circuit. Preferably, the device can easily be integrated into an antenna control and management device of a ‘hands-free’ system.

To this end, it proposes an antenna diagnostic device of a resonant circuit associated with an amplifier comprising a first transistor connected to a supply voltage and a second transistor connected to a ground and an amplifier output, the first transistor and the second transistor being mounted symmetrically and the amplifier output being located between the two transistors, said device comprising means for evaluating a current flowing in a connection of each of said transistors.

According to the present invention, it is proposed that said diagnostic device further comprises:
first means for generating an input signal connected to the first transistor,
second means for generating an input signal connected to the second transistor, and
electronic means presenting an output supplying an output signal representative of the potential difference between the first input and the second input.

In an original way, it is proposed here to generate an input signal at a transistor and to analyze the output voltage of the amplifier. Since this output is connected to a resonant circuit, the output voltage of the amplifier will not vary in the same way if the inductor of said resonant circuit, i.e. the antenna, is in open circuit or short-circuited or still suitably connected. Moreover, this diagnostic device can also be used by sending a continuous signal on one and then on the other of the transistors for determining whether there are short-circuit problems at the more global level of the resonant circuit. These checks were already performed in the prior art but generally required the implementation of an analog-to-digital converter which is no longer necessary with the diagnostic device proposed by the present invention.

In a preferred embodiment of a diagnostic device according to the present invention, the first transistor and the second transistor are, for example, both metal oxide semiconductor field effect transistors, known as MOSFETs.

A device according to the invention is preferably integrated into a circuit and then constitutes an element of an application-specific integrated circuit.

The present invention also relates to a control and management device of at least one antenna, comprising a diagnostic device as described above. Such a device is preferably an application-specific integrated circuit.

The invention further relates to a ‘hands free’ management system, comprising a control and management device of at least one antenna defined in the previous paragraph. Advantageously, this system comprises a control and management device and resonant circuits each comprising at least one resistor, one capacitor and one inductor, the control and management device takes the form of an application-specific integrated circuit mounted on a card, said card also carries the resonant circuit resistors and capacitors, and the at least one inductor is offset with respect to said card.

The invention also relates to a motor vehicle, comprising a ‘hands free’ management system defined in the previous paragraph.

Finally the invention proposes a method of diagnosing at least one antenna of a resonant circuit associated with an amplifier comprising a first transistor connected to a supply voltage and a second transistor connected to a ground and an amplifier output, the first transistor and the second transistor being mounted symmetrically and the amplifier output being located between the two transistors, said device comprising means for evaluating a current flowing in a connection of each of said transistors, the method comprising the following steps:
generation of a signal by only one of the transistors and excitation of the antenna concerned by said signal, for a predetermined period of time,
evaluation of the current in each of the connections equipped with means for evaluating a current,
evaluation of the amplifier output potential,
performance of a diagnosis by comparing the results of the evaluations carried out with the results corresponding to the measurements obtained when the antenna concerned is in normal operating conditions.

Such a process can be implemented with a device such as those described above. It offers the advantage of being able, at lower cost, to perform a complete diagnosis of a resonant circuit in particular comprising an antenna.

In such a method, it is advantageously provided that three signals are successively generated, a first continuous signal by one of the transistors, a second continuous signal by the other transistor and a variable signal in the form of at least one pulse by a single transistor. In this way, it is possible to detect a short circuit at the output of the amplifier and also an anomaly at the antenna.

Details and advantages of the present invention will better emerge from the following description, with reference to the accompanying schematic drawings in which:

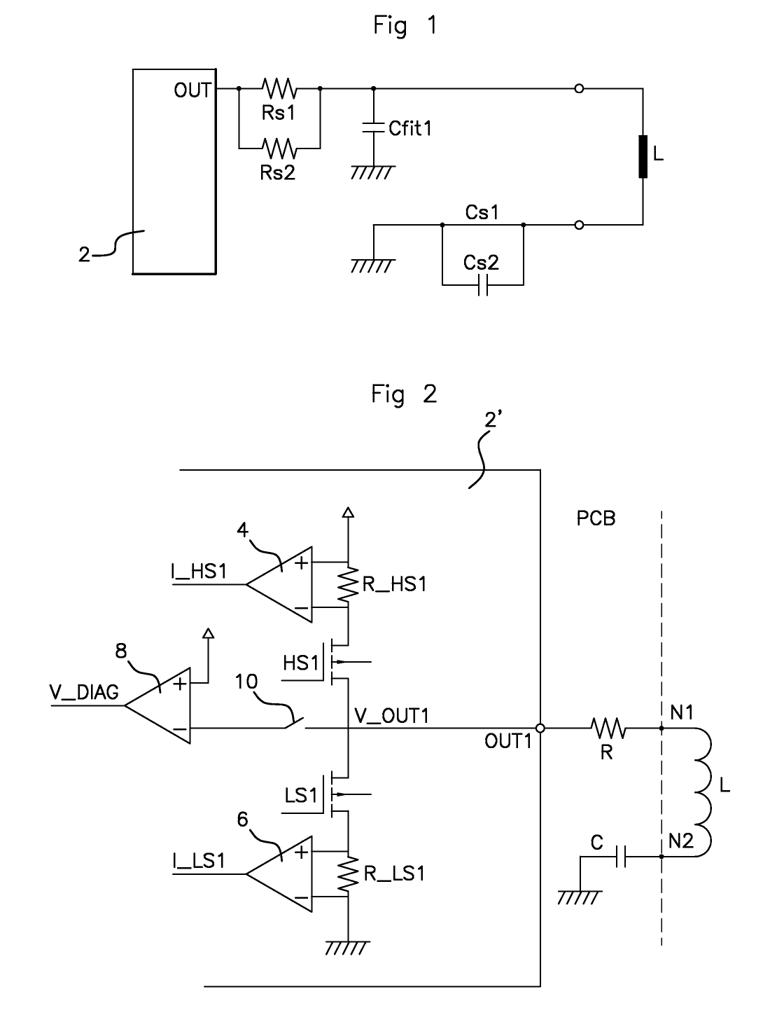

FIG. 1 is a schematic view of an oscillating circuit incorporating an antenna and a control and management device known to the prior art,

FIG. 2 is a schematic view of a device such as that in FIG. 1 to which the present invention applies,

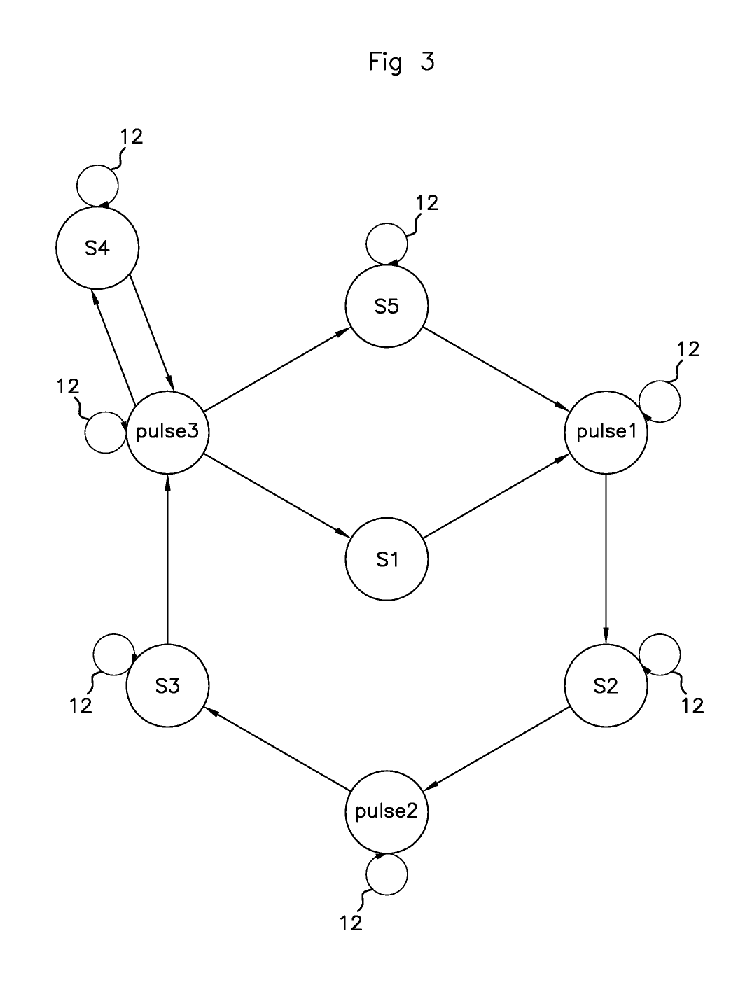

FIG. 3 schematically illustrates steps for implementing a method according to the present invention for performing a diagnosis of an antenna, and

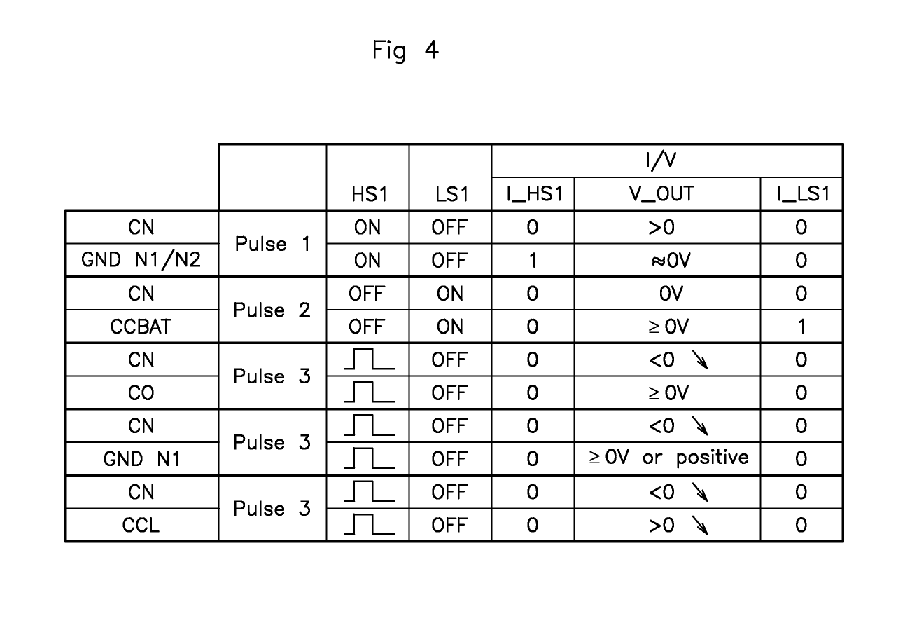

FIG. 4 is a table illustrating the results that can be obtained during the implementation of a method according to the present invention.

FIG. 1 represents a control and management device 2 of an antenna. On the left side of this figure, the control and management device 2 itself is to be seen, which has an output OUT to which a resonant circuit comprising an antenna L is connected.

The control and management device 2 is, for example, implemented in the form of an Application-Specific Integrated Circuit, also known as an ASIC.

The resonant circuit comprises, as already mentioned, the antenna L as well as resistors and capacitors. The circuit shown in FIG. 1 is a conventional circuit in an antenna half-bridge configuration. The corresponding resonant circuit is an RLC circuit in which the resistance is implemented by two resistors Rs1 and Rs2 in parallel. Similarly the capacitance is formed of a capacitor Cs1 and a capacitor Cs2 mounted in parallel. An isolating capacitor Cfit1 can also be seen in FIG. 1. Such a resonant circuit is known to the person skilled in the art and is not described in more detail here.

It should be noted that FIG. 1 shows a single resonant circuit with a single antenna L. However, the control and management device 2 may comprise multiple outputs to each of which a resonant circuit comprising an antenna would be connected. As an illustrative non-restrictive example, six outputs similar to the output OUT shown in FIG. 1 may, for example, be provided for a control and management device intended for a hands-free system for a motor vehicle.

FIG. 2 shows a control and management device 2′ incorporating a diagnostic device according to the present invention. This control and management device 2′ also incorporates a low-frequency driver, also known as an ‘LF Driver’. Just as for the prior art embodiment shown in FIG. 1, there is an output here referred to as OUT1 to which an RLC type of resonant circuit is connected with a resistor R, an inductor formed by the antenna L and a capacitor C.

The antenna L is connected between two connection points, a first connection point N1 and a second connection point N2. The resistor R is connected between the output OUT1 and the connection point N1 while the capacitor C is connected between the connection point N2 and the ground. Thus here is a half-bridge circuit as in FIG. 1. Just as for FIG. 1, a single antenna L is shown here associated with the control and management device 2′ but this control and management device is advantageously equipped with multiple outputs, not shown, to each of which a resonant circuit is connected such as the RLC resonant circuit illustrated in FIG. 2.

In a preferred embodiment, the control and management device 2′ is an application-specific integrated circuit, or ASIC, mounted on a printed circuit board. This printed circuit board, referred to as PCB in FIG. 2. As shown in FIG. 2, the PCB also receives the resistor R and the capacitor C. The antenna L is, for example, incorporated into a door of a motor vehicle.

FIG. 2 also shows schematically an output stage of the control and management device 2′. A person skilled in the art would recognize in this figure a symmetrical circuit, also called a ‘push-pull’ type of circuit, with two transistors. In the embodiment shown, a first transistor HS1 is a metal oxide semiconductor field-effect transistor (also known as a ‘MOSFET’). This first transistor HS1 is of the P-channel PNP type. The drain of this first transistor HS1 is connected to the power supply of the control and management device 2′. The source of this first transistor HS1 is connected to the output OUT1.

A second transistor LS1 is provided symmetrically to this first transistor HS1. This second transistor LS1 is also a MOSFET transistor. However, here it is an N-channel NPN transistor. The source of this second transistor LS1 is connected to the ground while the drain of this second transistor LS1 is connected to the output OUT1.

The ‘push-pull’ circuit of the first transistor HS1 with the second transistor LS1 creates an amplifier for a signal applied to the gates of these transistors. The means for generating this signal are incorporated in the control and management device 2′ but are not shown in FIG. 2.

FIG. 2 also shows first means for measuring the current flowing in the drain of the first transistor HS1. These first means comprise a resistor R_HS1 and a first measuring device 4 for measuring the potential at the terminals of the resistor R_HS1. This measurement performed by the first measuring device 4 at the terminals of a resistor of known value is used to determine the value of the current flowing through this resistor R_HS1. If this current is below a predetermined threshold, a signal I_HS1 output from the measuring device 4 takes the value 0 otherwise it takes the value 1.

In a similar way, there are second means for measuring the current at the source of the second transistor LS1. Here is a resistor R_LS1 mounted between the source of the second transistor LS1 and the ground and at the terminals of which a second measuring device 6 will measure the voltage so as to determine the current flowing through the resistor R_LS1 and therefore also the source of the second transistor LS1. A signal I_LS1 corresponding to the current flowing at the source of the second transistor LS1. This signal takes a value zero (0) if the current has an intensity less than a predetermined threshold and a value 1 otherwise.

The diagnostic device incorporated in the control and management device 2′ shown, in addition to the first means and second means of current measurement, has a comparator 8 which provides a signal V_DIAG.

The comparator 8 has two input terminals, a +terminal and a −terminal as well as an output. The +terminal is connected here to the supply voltage of the control and management device 2′. The −terminal of the comparator 8 is connected in the present embodiment to the output OUT1. The comparator 8 output delivers the signal V_DIAG. The latter is illustrative of the potential difference between a reference voltage corresponding to the supply voltage of the control and management device 2′ and the voltage V_OUT1 of the output OUT1. If the voltage V_OUT1 is greater than the reference voltage, the signal V_DIAG is equal to 1, and 0 otherwise.

The switch 10 is used for connecting the output OUT1 to the comparator 8 when a diagnosis is performed. FIGS. 3 and 4 illustrate a diagnostic method according to the present invention which will be described below with reference to these figures.

The diagnostic method proposed here is first of all intended to determine, like the diagnostic methods known to the prior art, whether the output, in the case of FIG. 2 the output OUT1, is short-circuited to the supply voltage or if one of the connection points N1 and/or N2 is short-circuited. In an innovative way, the method also proposes performing a test on the antenna L for determining whether it is in open circuit or on the contrary if the two connection points N1 and N2 thereof are short-circuited.

The process proposed here begins, for example, with a step S1 corresponding to an idle state of the diagnostic device (FIG. 3) in which the switch 10 (FIG. 2) is open. When the diagnostic device comes out of its idle state, it is proposed to perform a first diagnostic step, called step pulse1, for the purpose of determining whether the connection point N1 and/or the connection point N2 is short-circuited to the ground.

For performing this first diagnostic test, the first transistor HS1 is continuously controlled (ON position) for a predetermined time. During this period, the second transistor LS1 does not receive a signal (OFF position). In normal operating conditions, the signal I_HS1, for evaluating the passage of a current in the drain of the first transistor HS1, must be zero. On the other hand, in the event of a short-circuit to the ground of the connection point N1 or connection point N2, a current flows in the resistor R_HS1 at the output of the drain of the first transistor HS1, and the signal I_HS1 then equals 1. For performing the evaluation of the voltage V_OUT1 at the amplifier output OUT1, the switch 10 is in the closed position.

In FIG. 3, a waiting loop 12, adjacent to the step pulse1, illustrates in fact that the continuous signal is applied to the first transistor HS1 for a predetermined time period. At the end of this time period, a step S2 is used to transfer the results of measurement and/or evaluation performed in step pulse1. This step S2 is also associated with a waiting loop 12 intended to ensure that the resonant circuit is idle before performing a second measurement/evaluation.

The second measurement step is called step pulse2 in FIG. 3. During this measurement step, a signal is applied to the gate of the second transistor LS1 while the first transistor HS1 remains ‘idle’. In a similar manner to the diagnosis performed in step pulse1, a zero signal I_LS1 (no current in R_LS1) should be observed if the circuit is in normal operating conditions. However, if there is a short circuit to the supply voltage at the output OUT1, the signal I_LS1 will take the value 1.

Just as for step pulse1, a waiting loop 12 is associated with step pulse2 which is followed by a step S3. In the course of the latter, the results of the evaluations/measurements made in step pulse2 are transmitted and a waiting time symbolized by a waiting loop 12 is provided for enabling the resonant circuit to return to an idle state.

A third measurement step, called step pulse3, is performed. This measurement (or evaluation) step proposes, in an original way, applying at least one pulse at the input of the transistor HS1. Advantageously, about ten pulses, square-shaped, for example, will be applied at the input of the first transistor HS1. Pulse shapes other than that shown in FIG. 4 may be envisaged. Here also, a waiting loop 12 illustrates the time needed for applying the signal at the input of the first transistor HS1. The pulse frequency is, for example, 125 kHz which corresponds, for example, to the frequency of the low frequency driver (LF Driver) signals of the control and management device 2′. The input signal of the first transistor HS1 is amplified and injected into the RLC resonant circuit. If the circuit resonates normally, the antenna L is a priori correctly connected. However if the antenna L is in short circuit, one or two pulses are observed and no resonance. If the inductor corresponding to the antenna L is in open circuit, the oscillating signal is strongly attenuated. Thus the state of the antenna is successfully determined by observing the voltage V_OUT1 with the aid of the comparator 8. In FIG. 3, a step S4 corresponds to the measurement and analysis of the voltage V_OUT1 and transmission of the results.

After this third measurement step, the diagnostic method concludes or else a diagnosis is repeated. For example, there may be a return to idle mode (step S1) if no anomaly has been found. Otherwise, if an anomaly has been found a new diagnosis may be performed. In the latter case, a waiting time may be provided before restarting the diagnostic method. This waiting time forms step S5 in FIG. 3 which is also associated with a waiting loop 12 and first of all enables the resonant circuit to be placed in idle. For better management of the system, it is also useful to wait during this step S5 for a signal from the control and management device 2′ for restarting a diagnosis of the system.

The table in FIG. 4 is a summary table which, for each situation, indicates the expected results in the signals I_HS1, I_LS1 and for measuring the voltage V_OUT1, evaluated by the signal V_DIAG.

In the table in FIG. 4, the columns indicate, respectively and successively from left to right:
the state of the circuit on which the diagnosis is made,
the measurement step (pulse1, pulse2, pulse3),
the signal applied to the first transistor HS1,
the signal applied to the second transistor LS1,
the signal I_HS1 measured,
the voltage V_OUT1 measured,
the signal I_LS1 obtained.

The rows of the table alternately corresponding to normal conditions of measurement, i.e. to a circuit not displaying any fault and correctly connected, and to a circuit displaying a failure. Thus the following states are defined (see first left-hand column of the table in FIG. 4):
CN: normal condition,
GND N1/N2: short circuit to the ground at connection point N1 or at connection point N2,
CCBAT: short circuit to the supply voltage,
CO: open circuit,
GND N1: short circuit to the ground at connection point N1,
CCL: short circuit at the antenna L.

In this table, for the different states, the signal I_HS1 and the signal I_LS1 take either the value 0, or the value 1.

With regard to the signal V_OUT1 corresponding to the voltage at the output OUT1, the following scenarios apply:

In normal conditions during step pulse1, a positive voltage, close to the trigger voltage, is observed at voltage V_OUT1. On the other hand, in the case of a short circuit to the ground of connection point N1 or connection point N2, the voltage V_OUT1 is close to 0 V.

During step pulse2, in normal conditions, the voltage V_OUT1 is zero (0 V) whereas if there is a short circuit to the supply voltage the voltage V_OUT1 will be positive or zero.

In the case of step pulse3, in normal conditions, the voltage V_OUT becomes negative after the downward slope of the signal. On the other hand, in the event of an open circuit, this voltage V_OUT1 will be positive or zero. It will be also positive or zero in the case of a short circuit to the ground at connection point N1.

Finally, in the case of a short circuit at the antenna L, the voltage V_OUT will be positive after the downward slope of the signal.

The various results from the measurement steps performed (pulse1, pulse2, pulse3) are sent to means of analysis located at the control and management device 2′ or else within a microcontroller associated with this novel control and management device 2′. Using the proposed table in FIG. 4, it is thus possible to diagnose the various failures set out in this table.

The present invention thus enables a much greater number of failures to be diagnosed, compared with the prior art. In addition, for the failures already diagnosed in the state of the art, it is no longer necessary to synchronize the current measurements performed. Furthermore, whereas the devices of the prior art provided for the use of an analog-to-digital converter, it should be noted that the implementation of the present invention as proposed above does not require the use of such a converter.

It should also be noted in the preceding description that the means for performing the diagnosis can be fully integrated into the control and management device 2′, within an ASIC type integrated circuit.

A device for diagnosing an antenna and the control and management device described above can be used within a hands-free system of a motor vehicle. The control and management device described may be set up in an electronic unit while the antennas will be advantageously distributed at the interface between the interior and exterior of the vehicle so as to be able to detect and communicate with a users badge.

The present invention may, however, be implemented for other applications. It is not limited to antennas driven at low frequency (125 kHz) or others but can also be used in other frequency ranges, low or high.

The present invention is not limited to the preferred embodiment described above and shown in the drawing. It also relates to all the variant embodiments within the scope of the person skilled in the art.

1. An antenna (L) diagnostic device of a resonant circuit associated with an amplifier comprising a first transistor (HS1) connected to a supply voltage and a second transistor (LS1) connected to a ground and an amplifier output (OUT1), the first transistor (HS1) and the second transistor (LS1) being mounted symmetrically with respect to the amplifier output (OUT1) and the amplifier output (OUT1) being located between the two transistors, connected to each of the two transistors (LS1, HS1), said device comprising means for evaluating a current flowing in a connection of each of said transistors,
characterized in that it further comprises:
first means for generating an input signal connected to the first transistor,
second means for generating an input signal connected to the second transistor, and
electronic means (8) including an output supplying an output signal representative of the potential (V_OUT1) at the amplifier output.

2. The diagnostic device as claimed in claim 1, characterized in that the first transistor (HS1) and the second transistor (LS1) are both metal oxide semiconductor field effect transistors.

3. The device as claimed in claim 1, characterized in that the electronic means supplying an output signal representative of the potential at the amplifier output comprise a comparator device (8) with a first input connected to the amplifier output, a second input connected to a predetermined reference voltage and an output supplying an output signal representative of the potential difference between the first input and the second input.

4. A control and management device of at least one antenna (L), characterized in that it comprises a diagnostic device as claimed in claim 1.

5. The control and management device of at least one antenna (L) as claimed in claim 4, characterized in that it takes the form of an application-specific integrated circuit.

6. A hands-free management system, characterized in that it comprises a control and management device of at least one antenna (L) as claimed in claim 4.

7. The hands-free management system as claimed in claim 6, characterized in that it comprises a control and management device (2′) and resonant circuits each comprising at least one resistor (R), one capacitor (C) and one inductor (L), in that the control and management device (2′) takes the form of an application-specific integrated circuit mounted on a card (PCB), in that said card also carries the resonant circuit resistors (R) and capacitors (C), and in that the at least one inductor (L) is offset with respect to said card.

8. A motor vehicle, characterized in that it comprises a hands-free management system as claimed in claim 6.

9. A method of diagnosing at least one antenna of a resonant circuit associated with an amplifier comprising a first transistor (HS1) connected to a supply voltage and a second transistor (LS1) connected to a ground and an amplifier output (OUT1), the first transistor (HS1) and the second transistor (LS1) being mounted symmetrically and the amplifier output (OUT1) being located between the two transistors, said device comprising means for evaluating a current flowing in a connection of each of said transistors, characterized in that it comprises the following steps:
generation of a signal by only one of the transistors and excitation of the antenna (L) concerned by said signal, for a predetermined period of time,
evaluation of the current in each of the connections equipped with means for evaluating a current,
evaluation of the amplifier output potential,
performance of a diagnosis by comparing the results of the evaluations carried out with the results corresponding to the measurements obtained when the antenna concerned is in normal operating conditions.

10. The diagnostic method as claimed in claim 9, characterized in that three signals are successively generated, a first continuous signal by one of the transistors, a second continuous signal by the other transistor and a variable signal in the form of at least one pulse by a single transistor.

11. The device as claimed in claim 2, characterized in that the electronic means supplying an output signal representative of the potential at the amplifier output comprise a comparator device (8) with a first input connected to the amplifier output, a second input connected to a predetermined reference voltage and an output supplying an output signal representative of the potential difference between the first input and the second input.

12. A control and management device of at least one antenna (L), characterized in that it comprises a diagnostic device as claimed in claim 2.

13. A control and management device of at least one antenna (L), characterized in that it comprises a diagnostic device as claimed in claim 3.

14. A hands-free management system, characterized in that it comprises a control and management device of at least one antenna (L) as claimed in claim 5.

15. A motor vehicle, characterized in that it comprises a hands-free management system as claimed in claim 7.

16. A motor vehicle, characterized in that it comprises a hands-free management system as claimed in claim 14.
